(19) United States
(12) Patent Application Publication
(10) Pub. No.: US 2026/0150528 A1
(43) Pub. Date: May 28, 2026

(54) Display Device

(71) Applicant: LG Display Co., Ltd., Seoul (KR)

(72) Inventors: Kyu-Hwang Lee, Paju-si (KR); Jungho Bang, Paju-si (KR); Dongkyu Lee, Goyang-si (KR); Munchan Kang, Goyang-si (KR)

(21) Appl. No.: 19/319,091

(22) Filed: Sep. 4, 2025

(30) Foreign Application Priority Data
Nov. 26, 2024 (KR) 10-2024-0171113

(51) Int. Cl. H10K 59/124; H10K 59/80

(52) U.S. Cl. CPC H10K 59/124; H10K 59/873

(57) ABSTRACT

A display device includes a first insulating layer disposed on a substrate and exposing an edge area of the substrate, a second insulating layer disposed on the first insulating layer and having an end portion protruding outward beyond an end portion of the first insulating layer, and a third insulating layer disposed on the second insulating layer, covering an end portion of the second insulating layer, extending below the end portion of the second insulating layer, and covering a part of the edge area of the substrate exposed by the first insulating layer.

### CROSS-REFERENCE TO RELATED APPLICATION

The present application claims priority to Korean Patent Application No. 10-2024-0171113, filed November 26, 2024, the entire contents of which is incorporated herein for all purposes by this reference.

### TECHNICAL FIELD

The present specification relates to a display device.

### BACKGROUND

Display devices are applied to various electronic devices such as TVs, mobile phones, notebooks, tablets, etc.

Examples of display devices include organic light-emitting diode (OLED) display devices that emit light by itself, liquid crystal display (LCD) devices that require a separate light source, etc.

An OLED display device has a self-emissive element and thus does not require a separate light source, enabling the implementation of display devices of various designs. Recently, OLED display devices using a flexible substrate are being developed.

### SUMMARY OF THE INVENTION

When a substrate is formed of a flexible plastic material, the performance of a display device can be degraded due to moisture permeation. To prevent this, the substrate may have a multilayered structure. For example, the substrate may include a lower substrate layer and an upper substrate layer that are formed of a polymer material such as polyimide (PI), and an intermediate layer disposed between the lower substrate layer and the upper substrate layer and formed of an inorganic insulation material.

Meanwhile, when an external impact is applied to an edge area of the substrate, cracks can easily occur in a plurality of inorganic insulating layers disposed in the edge area of the substrate. These cracks may propagate to a display area, and there is a problem that moisture or oxygen introduced along the propagated cracks may cause deterioration of an organic light-emitting element. Cracks may also occur in a plurality of inorganic insulating layers disposed in the edge area of the substrate due to laser trimming for processing an appearance of a display panel. Accordingly, a structure in which the inorganic insulating layers are removed from the edge area of the substrate is being applied to a display device.

However, a problem that moisture in the air is absorbed into an upper substrate layer of the substrate in the exposed edge area of the substrate, causing peeling between the upper substrate layer and the intermediate layer may occur.

The object of the present specification is to provide a display device capable of preventing peeling between the upper substrate layer and the intermediate layer.

The object of the present specification is also to provide a display device capable of preventing cracks occurring in an edge area of a substrate from propagating to a display area.

The object of the present specification is also to provide a display device in which production energy required for production can be reduced and greenhouse gas emissions can be reduced.

Objects of the present specification are not limited to the above-described objects, and other objects that are not mentioned will be able to be clearly understood by those skilled in the art based on the following description.

According to embodiments of the present specification, there is provided a display device including a first insulating layer disposed on a substrate and exposing an edge area of the substrate, a second insulating layer disposed on the first insulating layer and having an end portion protruding outward beyond an end portion of the first insulating layer, and a third insulating layer disposed on the second insulating layer, covering an end portion of the second insulating layer, extending below the end portion of the second insulating layer, and covering a part of the edge area of the substrate exposed by the first insulating layer.

According to embodiments of the present specification, there is provided a display device including a substrate having a recess in an edge area, a first insulating layer disposed on the substrate and having an end portion protruding above the recess of the substrate, and a second insulating layer disposed on the first insulating layer, covering the end portion of the first insulating layer, extending below the end portion of the first insulating layer, and covering a part of the recess of the substrate.

According to the embodiments of the present specification, by covering the edge area of the substrate with the inorganic insulating layer, it is possible to prevent contact between the upper substrate layer of the substrate and moisture in the air, thereby preventing the peeling between the upper substrate layer of the substrate and the intermediate layer.

In addition, according to the embodiments of the present specification, by forming the inorganic insulating layer covering the edge area of the substrate and having a seam, even when cracks occur in the inorganic insulating layer in the edge area of the substrate, it is possible to prevent the cracks from propagating into the display area.

According to the embodiments of the present specification, the production energy required for producing the display device can be reduced due to the low defect rate of the display device caused by the cracks of the inorganic insulating layer and the peeling of the substrate, and greenhouse gas emissions can be reduced.

Effects of the present specification are not limited to the above-described effects, and other effects that are not mentioned will be able to be clearly understood by those skilled in the art based on the above detailed description.

### BRIEF DESCRIPTION OF THE DRAWINGS

FIG. 1 is a plan view of a display device according to one embodiment of the present specification.

FIG. 2 is a cross-sectional view of the display device along line II-II’ in FIG. 1 and schematically shows one sub-pixel of the display device according to one embodiment of the present specification.

FIG. 3 is a cross-sectional view of the display device along line III-III’ in FIG. 1 and schematically shows an edge area of the display device according to one embodiment of the present specification.

FIG. 4 is a schematic cross-sectional view showing the edge area of the display device according to one embodiment of the present specification.

FIG. 5 is a schematic cross-sectional view showing the edge area of the display device according to one embodiment of the present specification.

### DETAILED DESCRIPTION OF THE INVENTION

Advantages and features of the present specification and methods for achieving them will become clear by referencing embodiments described below in detail in conjunction with the accompanying drawings. However, the present specification is not limited to the embodiments disclosed below but will be implemented in various different forms, these embodiments are merely provided to make the disclosure of the present specification complete and fully inform those skilled in the art to which the present specification pertains of the scope of the present specification.

Since shapes, sizes, ratios, angles, numbers, etc. disclosed in the drawings for describing the embodiments of the present specification are illustrative, the present specification is not limited to the shown items. The same reference number denotes the same components throughout the specification. In addition, in describing the present specification, when it is determined that the detailed description of a related known technology may unnecessarily obscure the gist of the present specification, the detailed description thereof will be omitted. When “comprise,” “have,” “consist of,” or the like described herein are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be positioned between the two parts, for example, unless “immediately,” “directly,” or “close to” is used.

When the temporal relationship is described, when the temporal relationship is described using “after,” “subsequently,” “then,” “before,” or the like, it may also include a non-consecutive case unless “immediately” or “directly” is used.

Although terms such as first and second are used to describe various components, these components are not limited by these terms. These terms are only used to distinguish one component from another component. Therefore, a first component described below may be a second component within the technical spirit of the present specification.

In the description of components of the present specification, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between components that may be connected, coupled, joined, or attached indirectly unless otherwise stated specially.

When a component or a layer is described as “coming into contact with” or “overlapping” another component or layer, the component or the layer may come into direct contact with or directly overlap another component or layer, but it should be understood that still another component may be interposed between components that may come into indirect contact with and indirectly overlap each other unless otherwise stated specially.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, various technological interworking and driving are made possible, and the embodiments may be implemented independently of each other or implemented together in an associated relationship.

Hereinafter, various embodiments of the present specification will be described in detail with reference to the accompanying drawings.

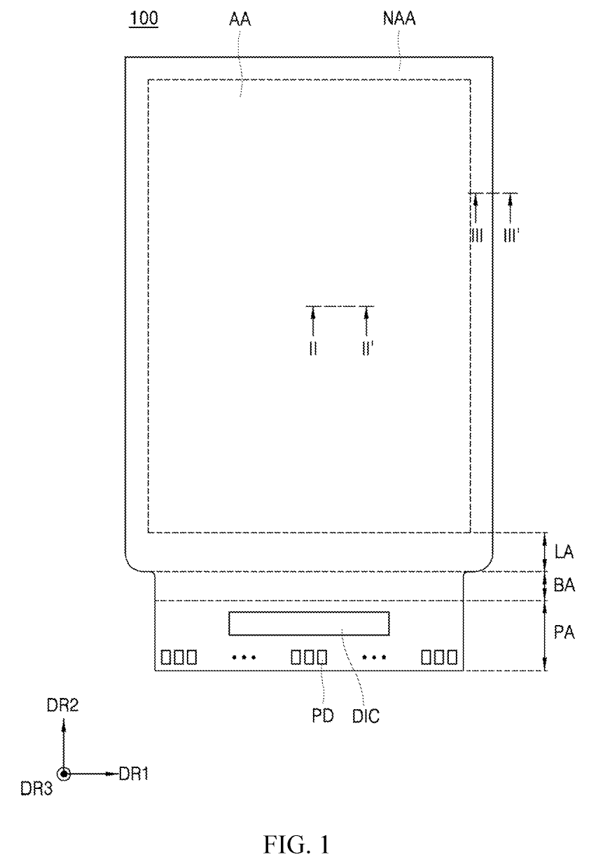

FIG. 1 is a plan view of a display device according to one embodiment of the present specification.

Referring to FIG. 1, a display device according to one embodiment of the present specification may include a display panel 100, a data driver DIC, a flexible printed circuit board, a timing controller, a power supplier, etc.

The display panel 100 may include a display area AA and a non-display area NAA. The display area AA and the non-display area NAA may be areas of a substrate. The display area AA is an area in which an image is implemented. The non-display area NAA is an area in which an image is not implemented and which is positioned outside the display area AA. An appearance of the display panel 100 may be formed by a laser trimming process.

The display area AA is an area in which a plurality of pixels are arranged. Each pixel may include a plurality of sub-pixels. The non-display area NAA is an area in which a gate driver, various link lines, various power supply lines, etc. are disposed.

The display area AA includes a plurality of data lines and a plurality of gate lines that are disposed to intersect each other. The plurality of gate lines may extend, for example, in a first direction DR1, and the plurality of data lines may extend, for example, in a second direction DR2. For example, the second direction DR2 is perpendicular with the first direction DR1. The data line transmits a data signal generated by the data driver DIC to the sub-pixel, and the gate line transmits gate signals generated by the gate driver to the sub-pixel.

The gate driver (not shown) may be disposed, for example, in the non-display area NAA positioned at left and right sides of the display area AA. The gate driver may be disposed directly on the substrate of the display panel 100 in a gate driver in panel (GIP) type.

The non-display area NAA may be disposed to surround the display area AA. For example, when the display area AA has a quadrangular shape, the non-display area NAA may be disposed at upper, lower, left, and right sides of the display area AA. The non-display area NAA positioned below the display area AA includes a pad area PA in which the data driver DIC and a flexible printed circuit board (not shown) are bonded, a link area LA and a bending area BA that are defined between the display area AA and the pad area PA.

The data driver DIC and the flexible printed circuit board may be bonded to the pad area PA by an anisotropic conductive film. The flexible printed circuit board may be bonded to pads PD disposed on an end portion of the pad area PA. The timing controller and the power supplier may be mounted on the flexible printed circuit board.

A part of the non-display area NAA of the display panel 100 may be bent at a predetermined curvature. A bent area of the non-display area NAA of the display panel 100 may be defined as the bending area BA.

As the bending area BA of the display panel 100 is bent, the pad area PA of the non-display area NAA may be positioned to overlap the display area AA on a back surface of the display area AA. Accordingly, the lower bezel area of the display device recognized from a front surface of the display device can be reduced.

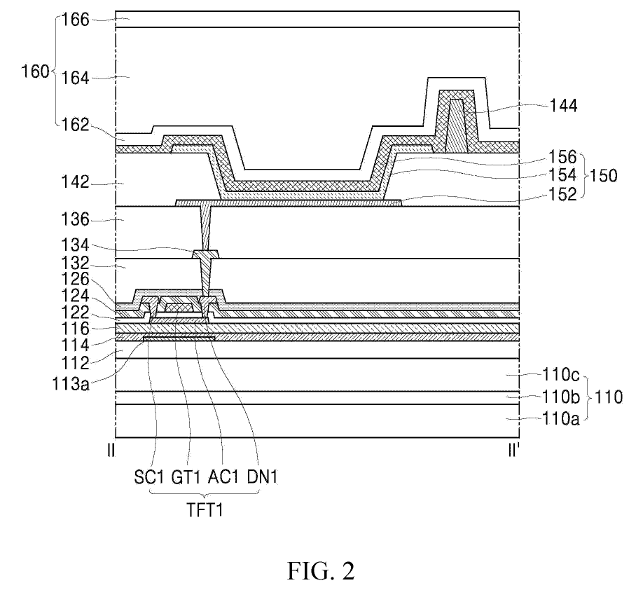

FIG. 2 is a cross-sectional view of the display device along line II-II’ in FIG. 1 and schematically shows one sub-pixel of the display device according to one embodiment of the present specification.

Referring to FIG. 2, the display device according to one embodiment of the present specification may include a first thin film transistor TFT1 and a light-emitting element 150 that are disposed in the display area AA of the substrate 110.

The substrate 110 may include an insulation material. The substrate 110 may include a flexible polymer material. To prevent the performance of the display device from being degraded due to moisture penetration, the substrate 110 may have a multilayered structure. For example, the substrate 110 may include a lower substrate layer 110a, an upper substrate layer 110c, and an intermediate layer 110b disposed between the lower substrate layer 110a and the upper substrate layer 110c. The lower substrate layer 110a and the upper substrate layer 110c may include a polymer material such as polyimide (PI). The intermediate layer 110b may include an inorganic insulation material such as silicon oxide, silicon nitride, and silicon oxynitride.

A first buffer layer 112 may be disposed on the substrate 110. The first buffer layer 112 may completely cover the display area AA of the substrate 110. The first buffer layer 112 may extend to the non-display area NAA of the substrate 110. The first buffer layer 112 may include an insulation material. For example, the first buffer layer 112 may include an inorganic insulation material such as silicon oxide, silicon nitride, and silicon oxynitride.

A second buffer layer 114 may be disposed on the first buffer layer 112. The second buffer layer 114 may cover the first buffer layer 112 and extend to the non-display area NAA of the substrate 110. For example, the second buffer layer 114 may have a different etching rate from the first buffer layer 112 during a wet etching process or a dry etching process. For example, the second buffer layer 114 may include a different material from the first buffer layer 112. The second buffer layer 114 may include an insulation material. For example, the second buffer layer 114 may include an inorganic insulation material such as silicon oxide, silicon nitride, and silicon oxynitride.

A light-blocking layer 113a may be disposed at a predetermined position between the first buffer layer 112 and the second buffer layer 114. The light-blocking layer 113a may include a metal material. For example, the light-blocking layer 113a may include a metal material such as aluminum (Al), chromium (Cr), copper (Cu), titanium (Ti), molybdenum (Mo), and tungsten (W).

A third buffer layer 116 may be disposed on the second buffer layer 114. The third buffer layer 116 may cover the second buffer layer 114 and extend to the non-display area NAA of the substrate 110. For example, the third buffer layer 116 may have a different etching rate from the second buffer layer 114 during a wet etching process or a dry etching process. For example, the third buffer layer 116 may include a different material from the second buffer layer 114. The third buffer layer 116 may include an insulation material. For example, the third buffer layer 116 may include an inorganic insulation material such as silicon oxide, silicon nitride, and silicon oxynitride.

A first thin film transistor TFT1 may be disposed on the light-blocking layer 113a. The first thin film transistor TFT1 may be electrically connected to the light-emitting element 150. The first thin film transistor TFT1 may include a first semiconductor layer AC1, a first gate electrode GT1, a first source electrode SC1, and a first drain electrode DN1. The first semiconductor pattern AC1 may be disposed on the third buffer layer 116.

The first semiconductor pattern AC1 may be disposed to overlap the light-blocking layer 113a. Light passing through the substrate 110 and traveling toward the first semiconductor pattern AC1 may be blocked by the light-blocking layer 113a. Accordingly, a change in the characteristics of the first thin film transistor TFT1 due to external light can be prevented. The first semiconductor pattern AC1 may include a semiconductor material. For example, the first semiconductor pattern AC1 may include a polycrystalline semiconductor material or an oxide semiconductor material.

A gate insulating layer 122 may be disposed on the first semiconductor pattern AC1. The gate insulating layer 122 may extend outward from the first semiconductor pattern AC1. For example, side surfaces of the first semiconductor pattern AC1 may be covered by the gate insulating layer 122. For example, the gate insulating layer 122 may cover the third buffer layer 116 and extend to the non-display area NAA of the substrate 110. For example, the gate insulating layer 122 may have a different etching rate from the third buffer layer 116 during a wet etching process or a dry etching process. The gate insulating layer 122 may include an insulation material. For example, the gate insulating layer 122 may include an inorganic insulation material such as silicon oxide, silicon nitride, and silicon oxynitride. The gate insulating layer 122 may include a material having a high dielectric constant. For example, the gate insulating layer 122 may include a high-k oxide such as hafnium oxide.

The first gate electrode GT1 may be disposed on the gate insulating layer 122. The first gate electrode GT1 may include a conductive material. For example, the first gate electrode GT1 may include a metal material such as aluminum (Al), chromium (Cr), copper (Cu), titanium (Ti), molybdenum (Mo), and tungsten (W). The first gate electrode GT1 may be electrically insulated from the first semiconductor pattern AC1 by the gate insulating layer 122. The first gate electrode GT1 may overlap a first channel area of the first semiconductor pattern AC1.

An interlayer insulating layer 124 may be disposed on the first gate electrode GT1. The interlayer insulating layer 124 may extend outward from the first gate electrode GT1. For example, side surfaces of the first gate electrode GT1 may be covered by the interlayer insulating layer 124. For example, the interlayer insulating layer 124 may cover the gate insulating layer 122 and extend to the non-display area NAA of the substrate 110. For example, the interlayer insulating layer 124 may have a different etching rate from the gate insulating layer 122 during a wet etching process or a dry etching process. The interlayer insulating layer 124 may include a different material from the gate insulating layer 122. The interlayer insulating layer 124 may include an insulation material. For example, the interlayer insulating layer 124 may include an inorganic insulation material such as silicon oxide, silicon nitride, and silicon oxynitride.

The first source electrode SC1 and the first drain electrode DN1 may be disposed on the interlayer insulating layer 124. The first source electrode SC1 and the first drain electrode DN1 may include a conductive material. For example, the first source electrode SC1 and the first drain electrode DN1 may include a metal material such as aluminum (Al), chromium (Cr), copper (Cu), titanium (Ti), molybdenum (Mo), and tungsten (W). For example, the first source electrode SC1 and the first drain electrode DN1 may include a different material from the first gate electrode GT1. For example, the first source electrode SC1 and the first drain electrode DN1 may have a multilayered structure of titanium (Ti)/aluminum (Al)/titanium (Ti).

The first source electrode SC1 and the first drain electrode DN1 may be electrically insulated from the first gate electrode GT1 by the interlayer insulating layer 124. The first source electrode SC1 may be electrically connected to a first source area of the first semiconductor pattern AC1. For example, the first source electrode SC1 may come into direct contact with the first source area of the first semiconductor pattern AC1 through a first source contact hole passing through the gate insulating layer 122 and the interlayer insulating layer 124. The first drain electrode DN1 may be electrically connected to a first drain area of the first semiconductor pattern AC1. For example, the first drain electrode DN1 may come into direct contact with the first drain area of the first semiconductor pattern AC1 through a first drain contact hole passing through the gate insulating layer 122 and the interlayer insulating layer 124.

A passivation layer 126 covering the first source electrode SC1 and the first drain electrode DN1 may be disposed on the interlayer insulating layer 124. The passivation layer 126 may cover the interlayer insulating layer 124 and extend to the non-display area NAA of the substrate 110. For example, the passivation layer 126 may have a different etching rate from the interlayer insulating layer 124 during a wet etching process or a dry etching process. The passivation layer 126 may include a different material from the interlayer insulating layer 124. The passivation layer 126 may include an insulation material. For example, the passivation layer 126 may include an inorganic insulation material such as silicon oxide, silicon nitride, and silicon oxynitride.

A first planarization layer 132 and a second planarization layer 136 are sequentially stacked on the passivation layer 126. The first planarization layer 132 and the second planarization layer 136 may cover a step caused by the first thin film transistor TFT1 to provide a flat surface. The first planarization layer 132 and the second planarization layer 136 may extend to the non-display area NAA of the substrate 110. For example, the first planarization layer 132 and the second planarization layer 136 may include an organic insulation material. For example, the first planarization layer 132 and the second planarization layer 136 may be formed of a photosensitive acryl-based or polyimide-based organic material. The second planarization layer 136 may include a different material from the first planarization layer 132.

An intermediate electrode 134 may be disposed on the first planarization layer 132. The light-emitting element 150 may be disposed on the second planarization layer 136. The light-emitting element 150 may include a first electrode 152, a light-emitting layer 154, and a second electrode 156. The light-emitting element 150 may be electrically connected to the first drain electrode DN1 of the first thin film transistor TFT1 through the intermediate electrode 134. For example, the intermediate electrode 134 may be connected to the first drain electrode DN1 by passing through the first planarization layer 132, and the first electrode 152 of the light-emitting element 150 may be connected to the intermediate electrode 134 by passing through the second planarization layer 136. The intermediate electrode 134 may include a conductive material. For example, the intermediate electrode 134 may include a metal material such as aluminum (Al), chromium (Cr), copper (Cu), titanium (Ti), molybdenum (Mo), and tungsten (W). For example, the intermediate electrode 134 may have a multilayered structure of titanium (Ti)/aluminum (Al)/titanium (Ti).

A bank layer 142 may be disposed on the second planarization layer 136. The bank layer 142 may include an organic insulation material. For example, the bank layer 142 may be formed of a photosensitive acryl-based or polyimide-based organic material. The bank layer 142 may cover an edge of the first electrode 152. The bank layer 142 may have an opening that exposes a part of the first electrode 152. The light-emitting layer 154 and the second electrode 156 of the light-emitting element 150 may be stacked on a part of the first electrode 152 exposed by the bank layer 142. A light-emitting area may be defined by the part of the first electrode 152 exposed by the opening of the bank layer 142. The first electrode 152 may include a conductive material. For example, the first electrode 152 may have high reflectivity. For example, the first electrode 152 may include a metal material such as aluminum (Al) or silver (Ag). The first electrode 152 may have a multilayered structure. For example, the first electrode 152 may have a structure in which a metal material such as aluminum (Al) or silver (Ag) is disposed between transparent conductive materials such as ITO and IZO.

The light-emitting layer 154 may extend onto the bank layer 142. The light-emitting layer 154 may include a light-emitting material layer formed of an organic material. The light-emitting layer 154 may have a multilayered structure. For example, the light-emitting layer 154 may include a first light-emitting common layer, a light-emitting material layer, and a second light-emitting common layer. For example, the first light-emitting common layer may include at least one of a hole injection layer (HIL) and a hole transport layer (HTL). The second light-emitting common layer may include at least one of an electron transport layer (ETL) and an electron injection layer (EIL).

For example, when the sub-pixels of each pixel emit light of different colors, the light-emitting material layer of each sub-pixel may be separated from the light-emitting material layer of an adjacent sub-pixel. The light-emitting material layer of each sub-pixel may be formed separately using a fine metal mask (FMM). A spacer 144 may be disposed on the bank layer 142. The spacer 144 can prevent damage to the bank layer 142 and the light-emitting material layer formed first in an adjacent sub-pixel by the FMM. The spacer 144 may include an organic insulation material. For example, the spacer 144 may be formed of a photosensitive acryl-based or polyimide-based organic material. The spacer 144 may include a different material from the bank layer 142.

The second electrode 156 may cover the light-emitting layer 154, the bank layer 142, and the spacer 144. The second electrode 156 may be disposed in common in adjacent sub-pixels. For example, the second electrode 156 may be disposed in common in all pixels in the display area AA. The second electrode 156 may extend to the non-display area NAA outside the display area AA. The second electrode 156 may include a conductive material. For example, the second electrode 156 may be a transparent electrode formed of a transparent conductive material such as ITO and IZO.

An encapsulation part 160 may be positioned on the light-emitting element 150. The encapsulation part 160 can prevent damage to the light-emitting elements 150 due to an external impact and moisture. The encapsulation part 160 may have a multilayered structure. For example, the encapsulation part 160 may include a first encapsulation insulating layer 162, a second encapsulation insulating layer 164, and a third encapsulation insulating layer 166 that are sequentially stacked. For example, the first encapsulation insulating layer 162 and the third encapsulation insulating layer 166 may include an inorganic insulation material, and the second encapsulation insulating layer 164 may include an organic insulation material. The encapsulation part 160 may extend to the non-display area NAA outside the display area AA.

For example, a touch sensor layer may be disposed on the encapsulation part 160.

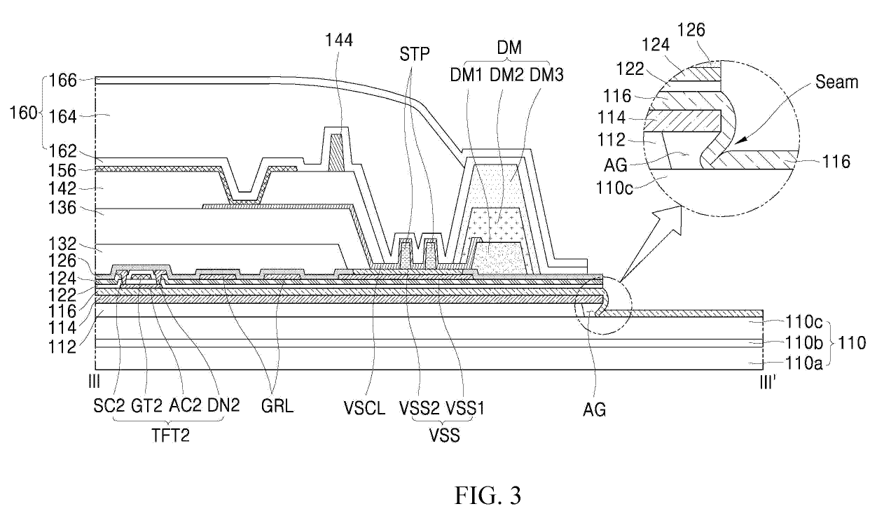

FIG. 3 is a cross-sectional view of the display device along line III-III’ in FIG. 1 and schematically shows an edge area of the display device according to one embodiment of the present specification.

Referring to FIG. 3, the display device according to one embodiment of the present specification may include a second thin film transistor TFT2, a gate routing line GRL, a low-potential power line VSS, and a dam structure DM that are disposed in the non-display area NAA of the substrate 110.

The first buffer layer 112 may be disposed on the substrate 110. The first buffer layer 112 may be disposed on the upper substrate layer 110c of the substrate 110. An end portion of the first buffer layer 112 may be positioned inside an end portion of the substrate 110. The end portion of the first buffer layer 112 may be spaced a predetermined distance from the end portion of the substrate 110. The first buffer layer 112 may expose the edge area of the substrate 110 without covering the edge area.

The second buffer layer 114 may be disposed on the first buffer layer 112. An end portion of the second buffer layer 114 may be positioned between the end portion of the first buffer layer 112 and the end of the substrate 110. The end portion of the second buffer layer 114 may protrude a predetermined length outward beyond the end portion of the first buffer layer 112, thereby forming an undercut structure.

The third buffer layer 116 may be disposed on the second buffer layer 114. The third buffer layer 116 may cover the end portion of the second buffer layer 114 and the edge area of the substrate 110. An end portion of the third buffer layer 116 may coincide with the end portion of the substrate 110. The third buffer layer 116 may cover a part of the edge area of the substrate 110 exposed by the first buffer layer 112. The third buffer layer 116 may cover most of the edge area of the substrate 110 exposed by the first buffer layer 112. The third buffer layer 116 may not cover the remaining portion of the edge area of the substrate 110 disposed below the second buffer layer 114 protruding outward from the first buffer layer 112. The third buffer layer 116 may extend below the end portion of the second buffer layer 114, then extend along the substrate 110, and have a seam between the end portion of the second buffer layer 114 and the substrate 110. Accordingly, an air gap AG surrounded by the substrate 110, the first buffer layer 112, the second buffer layer 114, and the third buffer layer 116 may be formed below the end portion of the second buffer layer 114.

A manufacturing process for forming the above structure will be briefly described. The first buffer layer 112 and the second buffer layer 114 are sequentially formed on the substrate 110 by a physical vapor deposition process or a chemical vapor deposition process. Next, the second buffer layer 114 and the first buffer layer 112 that are formed in the edge area of the substrate 110 are removed by a photolithography process and a dry etching process. Next, a part of the first buffer layer 112 below the second buffer layer 114 is selectively removed by a wet etching process. During the wet etching process, the first buffer layer 112 may be removed at a faster etching rate than the second buffer layer 114. After a photoresist is removed, the third buffer layer 116 is formed on the substrate 110 by a physical vapor deposition process or a chemical vapor deposition process.

According to one embodiment of the present specification, by allowing the third buffer layer, which is an inorganic insulating layer, to cover the edge area of the substrate, it is possible to prevent contact between the upper substrate layer of the substrate and moisture in the air, thereby preventing peeling between the upper substrate layer of the substrate and the intermediate layer.

In addition, according to one embodiment of the present specification, by having a seam in the third buffer layer covering the edge area of the substrate, even when cracks occur in the third buffer layer in the edge area of the substrate, the cracks can be prevented from propagating to the display area.

The second thin film transistor TFT2 may be disposed on the third buffer layer 116. The second thin film transistor TFT2 may be a component of the gate driver. The second thin film transistor TFT2 may include a second semiconductor layer AC2, a second gate electrode GT2, a second source electrode SC2, and a second drain electrode DN2. The second semiconductor pattern AC2 may be disposed on the third buffer layer 116.

The second semiconductor pattern AC2 may include a semiconductor material. For example, the second semiconductor pattern AC2 may include a polycrystalline semiconductor material or an oxide semiconductor material.

The gate insulating layer 122 may be disposed on the second semiconductor pattern AC2. The gate insulating layer 122 may extend outward from the second semiconductor pattern AC2. For example, side surfaces of the second semiconductor pattern AC2 may be covered by the gate insulating layer 122. For example, the gate insulating layer 122 may extend along an upper surface of the third buffer layer 116. An end portion of the gate insulating layer 122 may coincide with the end portion of the second buffer layer 114 or may be positioned inside the end portion of the second buffer layer 114.

The second gate electrode GT2 may be disposed on the gate insulating layer 122. The second gate electrode GT2 may include a conductive material. For example, the second gate electrode GT2 may include a metal material such as aluminum (Al), chromium (Cr), copper (Cu), titanium (Ti), molybdenum (Mo), and tungsten (W). The second gate electrode GT2 may be electrically insulated from the second semiconductor pattern AC2 by the gate insulating layer 122. The second gate electrode GT2 may overlap a first channel area of the second semiconductor pattern AC2.

The interlayer insulating layer 124 may be disposed on the second gate electrode GT2. The interlayer insulating layer 124 may extend outward from the second gate electrode GT2. For example, side surfaces of the second gate electrode GT2 may be covered by the interlayer insulating layer 124. The interlayer insulating layer 124 may extend along the upper surface of the gate insulating layer 122. An end portion of the interlayer insulating layer 124 may coincide with the end portion of the gate insulating layer 122 or may be positioned inside the end portion of the gate insulating layer 122.

The second source electrode SC2 and the second drain electrode DN2 may be disposed on the interlayer insulating layer 124. The second source electrode SC2 and the second drain electrode DN2 may include a conductive material. For example, the second source electrode SC2 and the second drain electrode DN2 may include a metal material such as aluminum (Al), chromium (Cr), copper (Cu), titanium (Ti), molybdenum (Mo), and tungsten (W). For example, the second source electrode SC2 and the second drain electrode DN2 may include a different material from the second gate electrode GT2. For example, the second source electrode SC2 and the second drain electrode DN2 may have a multilayered structure of titanium (Ti)/aluminum (Al)/titanium (Ti).

The second source electrode SC2 and the second drain electrode DN2 may be electrically insulated from the second gate electrode GT2 by the interlayer insulating layer 124. The second source electrode SC2 may be electrically connected to a second source area of the second semiconductor pattern AC2. For example, the second source electrode SC2 may come into direct contact with the second source area of the second semiconductor pattern AC2 through a second source contact hole passing through the gate insulating layer 122 and the interlayer insulating layer 124. The second drain electrode DN2 may be electrically connected to a second drain area of the second semiconductor pattern AC2. For example, the second drain electrode DN2 may come into direct contact with the second drain area of the second semiconductor pattern AC2 through a first drain contact hole passing through the gate insulating layer 122 and the interlayer insulating layer 124. The second source electrode SC2 and the second drain electrode DN2 of the second thin film transistor TFT2 may be formed of the same material as the first source electrode SC1 and the first drain electrode DN1 of the first thin film transistor TFT1.

The gate routing line GRL may be disposed on the interlayer insulating layer 124. The gate routing line GRL may be a line that transmits external power or signals to the gate driver. The gate routing line GRL may be disposed outside the second thin film transistor TFT2. In addition, a low-potential power line VSS may be disposed on the interlayer insulating layer 124. The low-potential power line VSS may be disposed outside the gate routing line GRL. The low-potential power line VSS may include a first low-potential power line VSS1 and a second low-potential power line VSS2. The gate routing line GRL and the first low-potential power line VSS1 may be formed of the same material as the second source electrode SC2 and the second drain electrode DN2 of the second thin film transistor TFT2.

The passivation layer 126 covering the second source electrode SC2, the second drain electrode DN2, and the gate routing line GRL may be disposed on the interlayer insulating layer 124. The passivation layer 126 may expose a part of the first low-potential power line VSS1. An end portion of the passivation layer 126 may coincide with the end portion of the second buffer layer 114 or may be positioned inside the end portion of the second buffer layer 114.

The first planarization layer 132 covering the second thin film transistor TFT2 and the gate routing line GRL may be disposed on the passivation layer 126. An end portion of the first planarization layer 132 may cover an end portion of the first low-potential power line VSS1 and may be positioned on the first low-potential power line VSS1. The second planarization layer 136 may be disposed on the first planarization layer 132. The first planarization layer 132 and the second planarization layer 136 may cover a step caused by the second thin film transistor TFT2 to provide a flat surface.

The second low-potential power line VSS2 may be disposed on a part of the first low-potential power line VSS1 exposed by the passivation layer 126. The second low-potential power line VSS2 may include the same material as the intermediate electrode 134 disposed on the display area AA of the substrate 110.

The second planarization layer 136 may be disposed on the first planarization layer 132. The second planarization layer 136 may cover an upper surface and side surfaces of the first planarization layer 132. An end portion of the second planarization layer 136 may be positioned on the second low-potential power line VSS2.

At least one stopper STP may be disposed on the second low-potential power line VSS2. The stopper STP can restrict a flow of the second encapsulation layer 164 having fluidity when the second encapsulation layer 164 is formed. The stopper STP may include the same material as the second planarization layer 136.

A low-potential power connection line VSCL may be disposed on the second planarization layer 136. The low-potential power connection line VSCL may extend outward beyond the end portion of the second planarization layer 136 and cover an upper surface of the second low-potential power connection line VSS2 and an upper surface and side surfaces of the stopper STP. The low-potential power connection line VSCL may include the same material as the first electrode 152 of the light-emitting element 150.

The bank layer 142 may be disposed on the second planarization layer 136. The bank layer 142 may include an opening that exposes a part of the low-potential power connection line VSCL. An end portion of the bank layer 142 may be positioned between the end portion of the second planarization layer 136 and the stopper STP.

The second electrode 156 of the light-emitting element 150 may be disposed on the bank layer 142 and connected to a part of the low-potential power connection line VSCL exposed by the opening of the bank layer 142.

The spacer 144 may be disposed on the bank layer 142 adjacent to the stopper STP. The spacer 144 disposed on an edge of the bank layer 142 in the non-display area NAA can restrict the flow of the second encapsulation layer 164 having fluidity when the second encapsulation layer 164 is formed.

A dam structure DM may be disposed on the passivation layer 126 with a predetermined width at the edge of the non-display area NAA of the substrate 110. Inner and outer surfaces of the dam structure DM may be sloped surfaces. A width of the dam structure DM may decrease toward the substrate 110. The inner surface of the dam structure DM may be a side surface adjacent to the stopper STP, and the outer surface thereof may be a surface facing the inner surface. The inner surface of the dam structure DM may be a side surface facing the display area AA, and the outer surface thereof may be a surface facing the inner surface. A lower end portion of the outer surface of the dam structure DM may be positioned inward beyond the end portion of the passivation layer 126.

The dam structure DM may include a plurality of dam layers DM1, DM2, and DM3. For example, the dam structure DM may include a first dam layer DM1 disposed on the passivation layer 126, a second dam layer DM2 covering an upper surface and side surfaces of the first dam layer DM1, and a third dam layer DM3 covering an upper surface and side surfaces of the second dam layer DM2. For example, a lower end portion of an outer surface of the third dam layer DM3 may be positioned inward beyond the end portion of the passivation layer 126. For example, the inner and outer surfaces of the third dam layer DM3 may provide the inner and outer surfaces of the dam structure DM. For example, the first dam layer DM1 may include the same material as the second planarization layer 136. For example, the second dam layer DM2 may include the same material as the bank layer 142. For example, the third dam layer DM3 may include the same material as the spacer 144. The dam structure DM may include the first to third dam layers DM1, DM2, and DM3, but is not limited thereto. In one embodiment, the dam structure DM may further include an additional dam layer including the same material as the first planarization layer 132 below the first dam layer DM1.

The encapsulation part 160 may be positioned on the second electrode 156. The encapsulation part 160 may have a multilayered structure. For example, the encapsulation part 160 may include a first encapsulation insulating layer 162, a second encapsulation insulating layer 164, and a third encapsulation insulating layer 166 that are sequentially stacked.

The first encapsulation insulating layer 162 may cover the second electrode 156, the bank layer 142, the spacer 144, the stopper STP, and the inner surface of the dam structure DM. The first encapsulation insulating layer 162 may cover the upper surface and side surfaces of the dam structure DM. An end portion of the first encapsulation insulating layer 162 may be positioned inward beyond the end portion of the passivation layer 126.

The dam structure DM can restrict the flow of the second encapsulation insulating layer 164 having fluidity when the second encapsulation insulating layer 164 is formed along with the stopper STP. For example, an end portion of the second encapsulation insulating layer 164 may be positioned on the inner surface of the dam structure DM.

The third encapsulation insulating layer 166 may cover an upper surface of the second encapsulation insulating layer 164. The third encapsulation insulating layer 166 may come into contact with the first encapsulation insulating layer 162 on the inner surface, upper surface, and outer surface of the dam structure DM. An end portion of the third encapsulation insulating layer 166 may be positioned inward beyond the end portion of the passivation layer 126. The end portion of the third encapsulation insulating layer 166 may coincide with the end portion of the first encapsulation insulating layer 162.

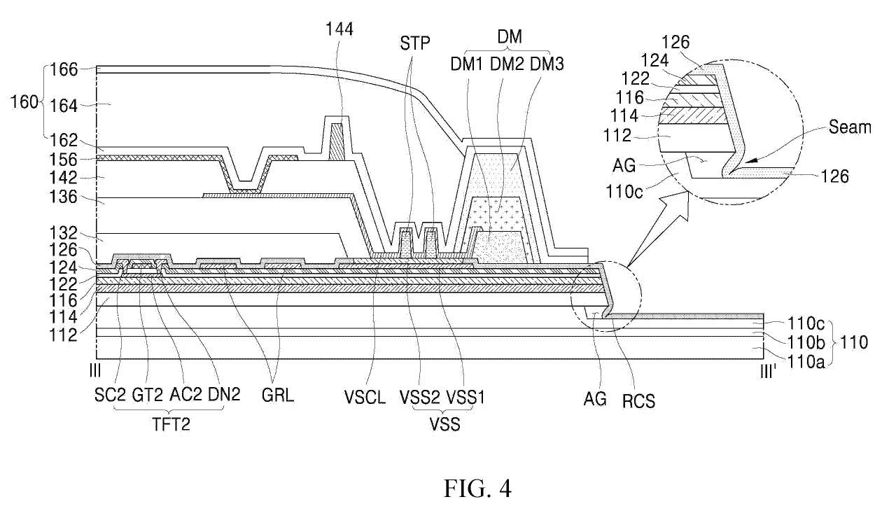

FIG. 4 is a schematic cross-sectional view showing the edge area of the display device according to one embodiment of the present specification. Hereinafter, the embodiment of FIG. 4 will be described mainly with respect to differences from the embodiment of FIG. 3.

Referring to FIG. 4, a recess RCS may be formed in the edge area of the substrate 110. The recess RCS may be formed in an edge area of the upper substrate layer 110c of the substrate 110. A surface of the recess RCS of the upper substrate layer 110c may include an uneven pattern.

The first buffer layer 112 may be disposed on the substrate 110. The first buffer layer 112 may be disposed on the upper substrate layer 110c of the substrate 110. An end portion of the first buffer layer 112 may be positioned inside an end portion of the substrate 110. The end portion of the first buffer layer 112 may be spaced a predetermined distance from the end portion of the substrate 110. The first buffer layer 112 may expose the recess RCS of the substrate 110 without covering the recess RCS. The end portion of the first buffer layer 112 may protrude a predetermined length above the recess RCS of the substrate 110 to form an undercut structure.

The second buffer layer 114 may be disposed on the first buffer layer 112. The end portion of the second buffer layer 114 may coincide with the end portion of the first buffer layer 112 or may be positioned inward beyond the end portion of the first buffer layer 112.

The third buffer layer 116 may be disposed on the second buffer layer 114. The end portion of the third buffer layer 116 may coincide with the end portion of the second buffer layer 114 or may be positioned inward beyond the end portion of the second buffer layer 114.

The second thin film transistor TFT2 may be disposed on the third buffer layer 116. The second thin film transistor TFT2 may include a second semiconductor layer AC2, a second gate electrode GT2, a second source electrode SC2, and a second drain electrode DN2.

The second semiconductor pattern AC2 may be disposed on the third buffer layer 116.

The gate insulating layer 122 may be disposed on the second semiconductor pattern AC2. The gate insulating layer 122 may extend outward from the second semiconductor pattern AC2. For example, the gate insulating layer 122 may extend along an upper surface of the third buffer layer 116. The end portion of the gate insulating layer 122 may coincide with the end portion of the third buffer layer 116 or may be positioned inward beyond the end portion of the third buffer layer 116.

The second gate electrode GT2 may be disposed on the gate insulating layer 122.

The interlayer insulating layer 124 may be disposed on the second gate electrode GT2. The interlayer insulating layer 124 may extend outward from the second gate electrode GT2. The interlayer insulating layer 124 may extend along the upper surface of the gate insulating layer 122. An end portion of the interlayer insulating layer 124 may coincide with the end portion of the gate insulating layer 122 or may be positioned inside the end portion of the gate insulating layer 122.

The second source electrode SC2 and the second drain electrode DN2 may be disposed on the interlayer insulating layer 124. For example, the second source electrode SC2 may come into direct contact with the second source area of the second semiconductor pattern AC2 through a second source contact hole passing through the gate insulating layer 122 and the interlayer insulating layer 124. For example, the second drain electrode DN2 may come into direct contact with the second drain area of the second semiconductor pattern AC2 through a first drain contact hole passing through the gate insulating layer 122 and the interlayer insulating layer 124.

The gate routing line GRL may be disposed on the interlayer insulating layer 124. The gate routing line GRL may be disposed outside the second thin film transistor TFT2. In addition, a low-potential power line VSS may be disposed on the interlayer insulating layer 124. The low-potential power line VSS may be disposed outside the gate routing line GRL.

The passivation layer 126 covering the second source electrode SC2, the second drain electrode DN2, and the gate routing line GRL may be disposed on the interlayer insulating layer 124. The passivation layer 126 may expose a part of the first low-potential power line VSS1.

The passivation layer 126 may cover the end portions of the first to third buffer layers 112, 114, and 116, the end portion of the gate insulating layer 122, the end portion of the interlayer insulating layer 124, and the edge area of the substrate 110. The end portion of the passivation layer 126 may coincide with the end portion of the substrate 110. The passivation layer 126 may cover a part of the recess RCS of the substrate 110 exposed by the first buffer layer 112. The passivation layer 126 may cover most of the recess RCS of the substrate 110 exposed by the first buffer layer 112. The passivation layer 126 may not cover the remaining portion of the recess RCS of the substrate 110 disposed below the first buffer layer 112 protruding above the recess RCS of the substrate 110. The passivation layer 126 may extend below the end portion of the first buffer layer 112, then extend along the recess RCS of the substrate 110, and have a seam between the end portion of the first buffer layer 112 and the substrate 110. Accordingly, the air gap AG surrounded by the substrate 110, the first buffer layer 112, and the passivation layer 126 may be formed below the end portion of the first buffer layer 112.

A manufacturing process for forming the above structure will be briefly described. The first buffer layer 112, the second buffer layer 114, the third buffer layer 116, the gate insulating layer 122, and the interlayer insulating layer 124 are sequentially formed on the substrate 110 by a physical vapor deposition process or a chemical vapor deposition process. Next, the first buffer layer 112, the second buffer layer 114, the third buffer layer 116, the gate insulating layer 122, and the interlayer insulating layer 124 that are formed on the edge area of the substrate 110 are removed by a photolithography process and a dry etching process. At this time, the edge area of the upper substrate layer 110c of the substrate 110 may also be etched. Next, a part of the upper substrate layer 110c of the substrate 110 is additionally removed by a dry etching process to form the recess RCS having a predetermined depth in the upper substrate layer 110c of the substrate 110. The uneven pattern may be formed on the surface of the recess RCS of the upper substrate layer 110c of the substrate 110 by a dry etching process. The upper substrate layer 110c may be removed at a faster etching rate than the first buffer layer 112, the second buffer layer 114, the third buffer layer 116, the gate insulating layer 122, and the interlayer insulating layer 124 by a dry etching process. After a photoresist is removed, the passivation layer 126 is formed on the substrate 110 by a physical vapor deposition process or a chemical vapor deposition process.

In FIG. 4, an example in which the passivation layer 126 has a seam below the end portion of the first buffer layer 112 and covers a part of the recess RCS of the substrate 110 has been described, but the embodiments of the present specification are not limited thereto. In some embodiments, instead of the passivation layer 126, one of the second buffer layer 114, the third buffer layer 116, the gate insulating layer 122, and the interlayer insulating layer 124 may have a seam below the end portion of the first buffer layer 112 and cover a part of the recess RCS of the substrate 110.

According to one embodiment of the present specification, by allowing one of the second buffer layer, the third buffer layer, the gate insulating layer, the interlayer insulating layer, and the passivation layer to cover the recess of the edge area of the substrate, it is possible to prevent contact between the upper substrate layer of the substrate and moisture in the air, thereby preventing peeling between the upper substrate layer and the intermediate layer of the substrate.

According to one embodiment of the present specification, since the surface of the recess of the substrate has the uneven pattern, it is possible to increase adhesion between the inorganic insulating layer covering the edge area of the substrate and the substrate, thereby preventing moisture in the air from flowing into the gap between the inorganic insulating layer and the substrate.

In addition, according to one embodiment of the present specification, by having a seam in the inorganic insulating layer covering the edge area of the substrate, even when cracks occur in the inorganic insulating layer in the edge area of the substrate, it is possible to prevent the cracks from propagating into the display area.

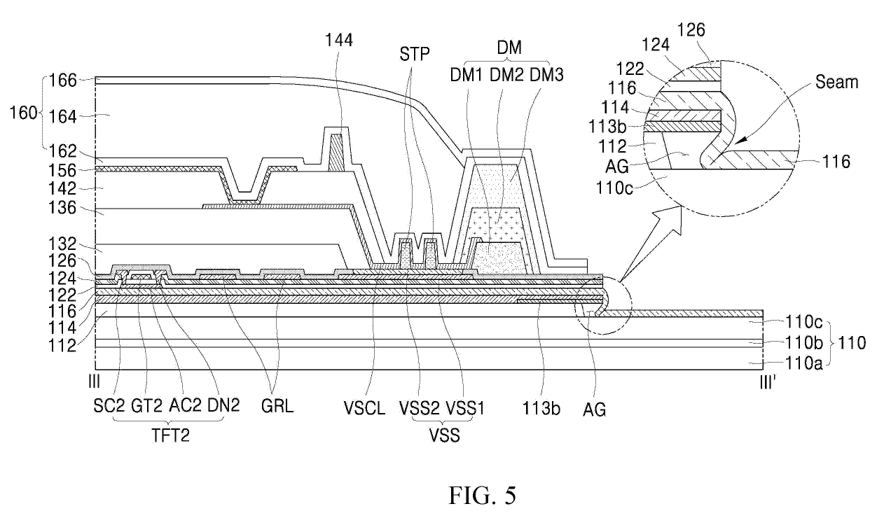

FIG. 5 is a schematic cross-sectional view showing the edge area of the display device according to one embodiment of the present specification. Hereinafter, the embodiment of FIG. 5 will be described mainly with respect to differences from the embodiment of FIG. 3.

Referring to FIG. 5, the first buffer layer 112 may be disposed on the substrate 110. The first buffer layer 112 may be disposed on the upper substrate layer 110c of the substrate 110. The end portion of the first buffer layer 112 may be positioned inside the end portion of the substrate 110. The end portion of the first buffer layer 112 may be spaced a predetermined distance from the end portion of the substrate 110. The first buffer layer 112 may expose the edge area of the substrate 110 without covering the edge area.

The second buffer layer 114 may be disposed on the first buffer layer 112. The end portion of the second buffer layer 114 may be positioned between the end portion of the first buffer layer 112 and the end of the substrate 110. The end portion of the second buffer layer 114 may protrude a predetermined length outward beyond the end portion of the first buffer layer 112.

A metal layer 113b having a predetermined width may be disposed between the first buffer layer 112 and the second buffer layer 114 inward beyond the edge area of the substrate 110 exposed by the first buffer layer 112. The metal layer 113b may be disposed along upper, lower, and left edge areas of the substrate 110. The metal layer 113b may have an inner end portion facing the display area AA of the substrate 110 and an outer end portion facing the edge of the substrate 110. The outer end portion of the metal layer 113b may be positioned between the end portion of the first buffer layer 112 and the end portion of the substrate 110. The outer end portion of the metal layer 113b may coincide with the end portion of the second buffer layer 114. The outer end portion of the metal layer 113b and the end portion of the second buffer layer 114 may protrude a predetermined length outward beyond the end portion of the first buffer layer 112, thereby forming an undercut structure.

The third buffer layer 116 may be disposed on the second buffer layer 114. The third buffer layer 116 may cover the end portion of the second buffer layer 114, the end portion of the metal layer 113b, and the edge area of the substrate 110. The end portion of the third buffer layer 116 may coincide with the end portion of the substrate 110. The third buffer layer 116 may cover most of the edge area of the substrate 110 exposed by the first buffer layer 112. The third buffer layer 116 may not cover a part of the edge area of the substrate 110 disposed below the metal layer 113b protruding outward from the first buffer layer 112. The third buffer layer 116 may extend below the outer end portion of the metal layer 113b, then extend along the substrate 110, and have a seam between the outer end portion of the metal layer 113b and the substrate 110. Accordingly, the air gap AG surrounded by the substrate 110, the first buffer layer 112, the metal layer 113b, and the third buffer layer 116 may be formed below the outer end portion of the metal layer 113b.

A manufacturing process for forming the above structure will be briefly described. The first buffer layer 112, the metal layer 113b, and the second buffer layer 114 are sequentially formed on the substrate 110 by a physical vapor deposition process or a chemical vapor deposition process. Next, the second buffer layer 114 and the first buffer layer 112 that are formed in the edge area of the substrate 110 are removed by a photolithography process and a dry etching process. Next, a part of the first buffer layer 112 below the metal layer 113b is selectively removed by a wet etching process. During the wet etching process, the first buffer layer 112 may be removed at a faster etching rate than the metal layer 113b. After a photoresist is removed, the third buffer layer 116 is formed on the substrate 110 by a physical vapor deposition process or a chemical vapor deposition process.

According to one embodiment of the present specification, by allowing the third buffer layer, which is an inorganic insulating layer, to cover the edge area of the substrate, it is possible to prevent contact between the upper substrate layer of the substrate and moisture in the air, thereby preventing peeling between the upper substrate layer of the substrate and the intermediate layer.

In addition, according to one embodiment of the present specification, by having a seam in the third buffer layer covering the edge area of the substrate, even when cracks occur in the third buffer layer in the edge area of the substrate, the cracks can be prevented from propagating to the display area.

According to one embodiment of the present specification, since the inorganic insulating layer below the metal layer is removed by using the metal layer as a mask to form an undercut structure, there is no limitation on the material of the inorganic insulating layer disposed on the metal layer, and the formation of the undercut structure can be made easier.

A display device according to various embodiments of the present specification may be described as follows.

According to embodiments of the present specification, there is provided a display device including a first insulating layer disposed on a substrate and exposing an edge area of the substrate, a second insulating layer disposed on the first insulating layer and having an end portion protruding outward beyond an end portion of the first insulating layer, and a third insulating layer disposed on the second insulating layer, covering an end portion of the second insulating layer, extending below the end portion of the second insulating layer, and covering a part of the edge area of the substrate exposed by the first insulating layer.

According to some embodiments of the present specification, an end portion of the third insulating layer may coincide with an end portion of the substrate.

According to some embodiments of the present specification, the third insulating layer may have a seam between the end portion of the second insulating layer and the substrate.

According to some embodiments of the present specification, an air gap surrounded by the substrate, the first insulating layer, the second insulating layer, and the third insulating layer may be formed below the end portion of the second insulating layer.

According to some embodiments of the present specification, the display device may further include a fourth insulating layer disposed on the third insulating layer, in which an end portion of the fourth insulating layer may coincide with the end portion of the second insulating layer or may be positioned inward beyond the end portion of the second insulating layer.

According to some embodiments of the present specification, the display device may further include a dam structure positioned inward beyond the end portion of the first insulating layer and disposed on the third insulating layer, and at least one encapsulation insulating layer covering an upper surface and side surfaces of the dam structure.

According to some embodiments of the present specification, an end portion of the at least one encapsulation insulating layer may be positioned inward beyond the end portion of the second insulating layer.

According to some embodiments of the present specification, the display device may further include a metal layer positioned inward beyond the edge area of the substrate exposed by the first insulating layer, disposed between the first insulating layer and the second insulating layer, and having a predetermined width. An outer end portion of the metal layer may coincide with the end portion of the second insulating layer.

According to some embodiments of the present specification, the third insulating layer may have a seam between the outer end portion of the metal layer and the substrate.

According to some embodiments of the present specification, an air gap surrounded by the substrate, the first insulating layer, the metal layer, and the third insulating layer may be formed below the outer end portion of the metal layer.

According to embodiments of the present specification, there is provided a display device including a substrate having a recess in an edge area, a first insulating layer disposed on the substrate and having an end portion protruding above the recess of the substrate, and a second insulating layer disposed on the first insulating layer, covering the end portion of the first insulating layer, extending below the end portion of the first insulating layer, and covering a part of the recess of the substrate.

According to some embodiments of the present specification, an end portion of the second insulating layer may coincide with an end portion of the substrate.

According to some embodiments of the present specification, the second insulating layer may have a seam between the end portion of the first insulating layer and the substrate.

According to some embodiments of the present specification, the display device may further include at least one insulating layer disposed between the first insulating layer and the second insulating layer.

According to some embodiments of the present specification, an end portion of the at least one insulating layer may coincide with the end portion of the first insulating layer or may be positioned inward beyond the end portion of the first insulating layer.

According to some embodiments of the present specification, the display device may further include a dam structure positioned inward beyond the end portion of the first insulating layer and disposed on the second insulating layer, and at least one encapsulation insulating layer covering an upper surface and side surfaces of the dam structure.

According to some embodiments of the present specification, an end portion of the at least one encapsulation insulating layer may be positioned inward beyond the end portion of the first insulating layer.

Although the embodiments of the present specification have been described in more detail with reference to the accompanying drawings, the present specification is not necessarily limited to these embodiments, and various modifications may be carried out without departing from the technical spirit of the present specification. Accordingly, the embodiments disclosed in the present specification are not intended to limit the technical spirit of the present specification, but are intended to describe the technical spirit of the present specification and the scope of the technical spirit of the present specification is not limited by these embodiments. Accordingly, it should be understood that the above-described embodiments are illustrative and not restrictive in all aspects.

What is claimed is:

1. A display device comprising:
a substrate;
a first insulating layer disposed on the substrate and exposing an edge area of the substrate;
a second insulating layer disposed on the first insulating layer and having an end portion protruding outward beyond an end portion of the first insulating layer; and
a third insulating layer disposed on the second insulating layer, covering an end portion of the second insulating layer, extending below the end portion of the second insulating layer, and covering a part of the edge area of the substrate exposed by the first insulating layer.

2. The display device of claim 1, wherein an end portion of the third insulating layer coincides with an end portion of the substrate.

3. The display device of claim 1, wherein the third insulating layer has a seam between the end portion of the second insulating layer and the substrate.

4. The display device of claim 1, wherein an air gap surrounded by the substrate, the first insulating layer, the second insulating layer, and the third insulating layer is formed below the end portion of the second insulating layer.

5. The display device of claim 1, further comprising a fourth insulating layer disposed on the third insulating layer,
wherein an end portion of the fourth insulating layer coincides with the end portion of the second insulating layer or is positioned inward beyond the end portion of the second insulating layer.

6. The display device of claim 1, further comprising:
a dam structure positioned inward beyond the end portion of the first insulating layer and disposed on the third insulating layer; and
at least one encapsulation insulating layer covering an upper surface and side surfaces of the dam structure.

7. The display device of claim 6, wherein an end portion of the at least one encapsulation insulating layer is positioned inward beyond the end portion of the second insulating layer.

8. The display device of claim 1, further comprising a metal layer positioned inward beyond the edge area of the substrate exposed by the first insulating layer, disposed between the first insulating layer and the second insulating layer, and having a predetermined width, and
wherein an outer end portion of the metal layer coincides with the end portion of the second insulating layer.

9. The display device of claim 8, wherein the third insulating layer has a seam between the outer end portion of the metal layer and the substrate.

10. The display device of claim 8, wherein an air gap surrounded by the substrate, the first insulating layer, the metal layer, and the third insulating layer is formed below the outer end portion of the metal layer.

11. A display device comprising:
a substrate having a recess in an edge area;
a first insulating layer disposed on the substrate and having an end portion protruding above the recess of the substrate; and
a second insulating layer disposed on the first insulating layer, covering the end portion of the first insulating layer, extending below the end portion of the first insulating layer, and covering a part of the recess of the substrate.

12. The display device of claim 11, wherein an end portion of the second insulating layer coincides with an end portion of the substrate.

13. The display device of claim 11, wherein the second insulating layer has a seam between the end portion of the first insulating layer and the substrate.

14. The display device of claim 11, further comprising at least one insulating layer disposed between the first insulating layer and the second insulating layer.

15. The display device of claim 14, wherein an end portion of the at least one insulating layer coincides with the end portion of the first insulating layer or is positioned inward beyond the end portion of the first insulating layer.

16. The display device of claim 11, further comprising:
a dam structure positioned inward beyond the end portion of the first insulating layer and disposed on the second insulating layer; and
at least one encapsulation insulating layer covering an upper surface and side surfaces of the dam structure.

17. The display device of claim 16, wherein an end portion of the at least one encapsulation insulating layer is positioned inward beyond the end portion of the first insulating layer.

18. The display device of claims claim 11, wherein a surface of the recess includes an uneven pattern.
